(19) United States
(12) Patent Application Publication
(10) Pub. No.: US 2002/0085362 A1
(43) Pub. Date: Jul. 4, 2002

(54) Low cost feature to indicate package orientation

(76) Inventors: Joshua J. Malone, Plano, TX (US); Jeffrey E. Faris, Richardson, TX (US)

Correspondence Address: TEXAS INSTRUMENTS INCORPORATED, P O BOX 655474, M/S 3999, DALLAS, TX, 75265

(21) Appl. No.: 10/028,015

(22) Filed: Dec. 21, 2001

Related U.S. Application Data
(60) Provisional application No. 60/258,993, filed on Dec. 29, 2000.

(51) Int. Cl. H05K 7/02; H05K 3/36

(52) U.S. Cl. 361/807; 29/830; 29/831; 174/260

(57) ABSTRACT

An integrated circuit package and method that provides excellent visibility to the orientation of the package substrate throughout all stages of the device assembly process, and over a wide range of ambient light conditions. The package uses an existing metalization layer to designate a reference corner of the package. A lower portion 102 of the package includes an intermediate metalization layer patterned on the surface of the lower portion. This metalization is used to connect the device 104 being packaged with circuitry outside the package. An upper portion 108 of the package is supported by the lower portion of the package and sandwiches the intermediate layer. At least one corner of the upper layer 108 exposes a region 110 of the intermediate metalization layer. This region is highly visible since it is reflective and located outside of the package cavity. The metalization region 110 may also be plated or tinned to increase its visibility. Unlike orientation designators located on the top of a package, the metalization region 110 is visible before the package has been completed. This is useful when manufacturing steps rely on human intervention or assistance. The preceding abstract is submitted with the understanding that it only will be used to assist in determining, from a cursory inspection, the nature and gist of the technical disclosure as described in 37 C.F.R. § 1.72(b). In no case should this abstract be used for interpreting the scope of any patent claims.

### FIELD OF THE INVENTION

This invention relates to the field of integrated circuit packaging, more particularly to methods of indicating the orientation of a semiconductor package.

### BACKGROUND OF THE INVENTION

Integrated circuit packages use a variety of means to indicate the orientation of the package. Integrated circuits encapsulated in plastic often have an indentation on the surface of the package to indicate the location of pin one of the package. Other packages used a painted dot, or a chamfered corner to indication the proper orientation. While the indentation in a plastic package is essentially cost free, each of the other means of marking the orientation of the package results in added package cost. The alternate methods also have other shortcomings. For example, marking the package lid does not provide a reference during the fabrication of the package. Likewise, a chamfer on a package corner may be difficult to see under certain conditions. While these shortcomings are of no importance for many integrated circuits, the assembly of which is completely automated, improper keying during hand assembly operations leads to expensive waste in the manufacture of some integrated circuits, most notably microelectromechanical systems (MEMS). Furthermore, some electro-optic MEMS devices typically use a glass plate for the package lid. Markings on the glass lid can cause unwanted reflections that degrade the performance of the device. Additionally, markings on the glass are not available to use to orient the package during assembly.

What is needed is a method of indicating the orientation of an integrated circuit package that is easily visible over all extremes of ambient light, is available for reference during all stages of packaging, and does not add significant cost to the package.

### SUMMARY OF THE INVENTION

Objects and advantages will be obvious, and will in part appear hereinafter and will be accomplished by the present invention which provides a method and system for a low cost feature to indicate package orientation. One embodiment of the invention provides a substrate for a device package. The package substrate comprising: a lower portion of a package: an intermediate metalization layer on a top surface of the lower portion; an upper portion of the package on the top surface of the lower portion, a corner portion of the intermediate metalization layer remaining visible beyond the extent of the upper portion for indicating an orientation of the substrate.

According to another embodiment, a method of forming a device package is provided. The method comprising: providing a lower portion of a package; providing an intermediate metalization layer on a top surface of the lower portion; providing an upper portion of the package on the top surface of the lower portion, a corner portion of the intermediate metalization layer remaining visible beyond the extent of the upper portion for indicating an orientation of the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an exploded perspective view of a package according to one embodiment of the present invention showing the layers used to form the package substrate.

FIG. 2 is an exploded perspective view of sheets of material laminated to form the package of FIG. 1.

FIG. 3 is an exploded perspective view of the sheets of material of FIG. 2 with additional voids created to provide mechanical access to a reference plane.

### DETAILED DESCRIPTION OF THE PREFERRED EMBODIMENTS

A new integrated circuit package and method of forming a package has been developed that provides excellent visibility to the orientation of the package substrate throughout all stages of the device assembly process, and over a wide range of ambient light conditions. The package uses an existing metalization layer to designate a reference corner of the package. Since an existing layer is used, virtually no additional cost is incurred to use the new orientation indicator.

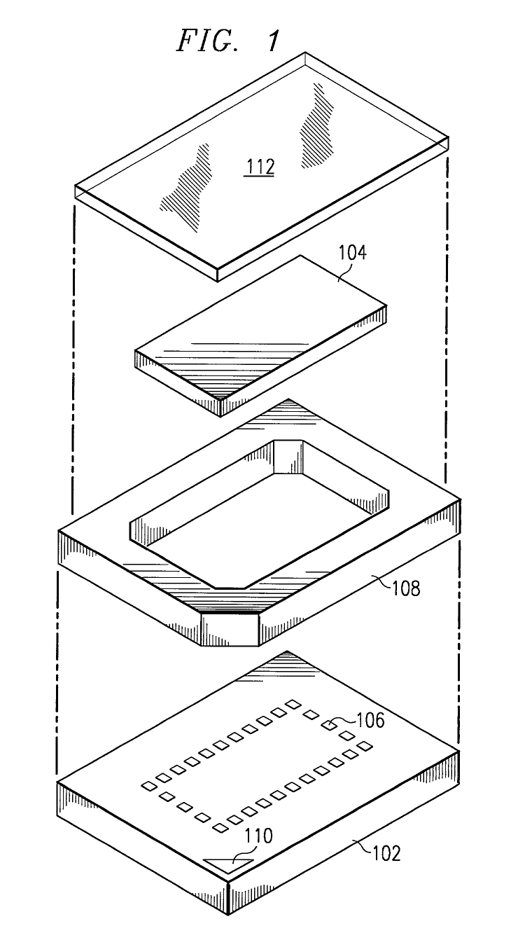

FIG. 1 is an exploded perspective view of a package according to one embodiment of the present invention showing the layers used to form the package substrate. In FIG. 1, a lower portion 102 of the package includes an intermediate metalization layer patterned on the surface of the lower portion. This metalization is used to connect the device 104 being packaged with circuitry outside the package.

The lower portion 102 of the package is formed through known methods. The lower portion 102 may be laminated from several layers with metalization between the layers. Connections between the layers of metalization complete connections between the bond pads 106 on the interior of the package and package leads, not shown, on the bottom of the package. Alternatively, the metalization is preformed to extend through the lower portion 102 of the package and the material forming the lower portion of the package is formed around the metalization. The lower portion 102 of the package typically is ceramic, but may be polyamide, plastic, or other materials.

An upper portion 108 of the package is supported by the lower portion of the package and sandwiches the intermediate layer. At least one corner of the upper layer 108 is cut back to expose a region 110 of the intermediate metalization layer. This region is highly visible since it is reflective and located outside of the package cavity. The metalization region 110 may also be plated or tinned to increase its visibility. The metalization region 110 typically is electrically isolated from the remainder of the metalization conductors used to connect the packaged device 104 with the external circuitry.

Unlike orientation designators located on the top of a package, the metalization region 110 is visible before the package has been completed. This is useful when manufacturing steps rely on human intervention or assistance.

After the device 104 is installed on the package substrate, it is sealed in the package by a lid 112. The lid likely is a glass plate, but may be a metal, ceramic, or plastic cover or formed from another material. The disclosed package is useful for packaging many types of integrated circuits, but is most useful for packaging electro-optical devices such a micromirror array. Electro-optical devices use a transparent lid to allow light to enter and exit the package. Traditional methods of indicating the orientation of the package, such as an ink spot in one corner of the package, may create unwanted reflections or other aberrations in the window.

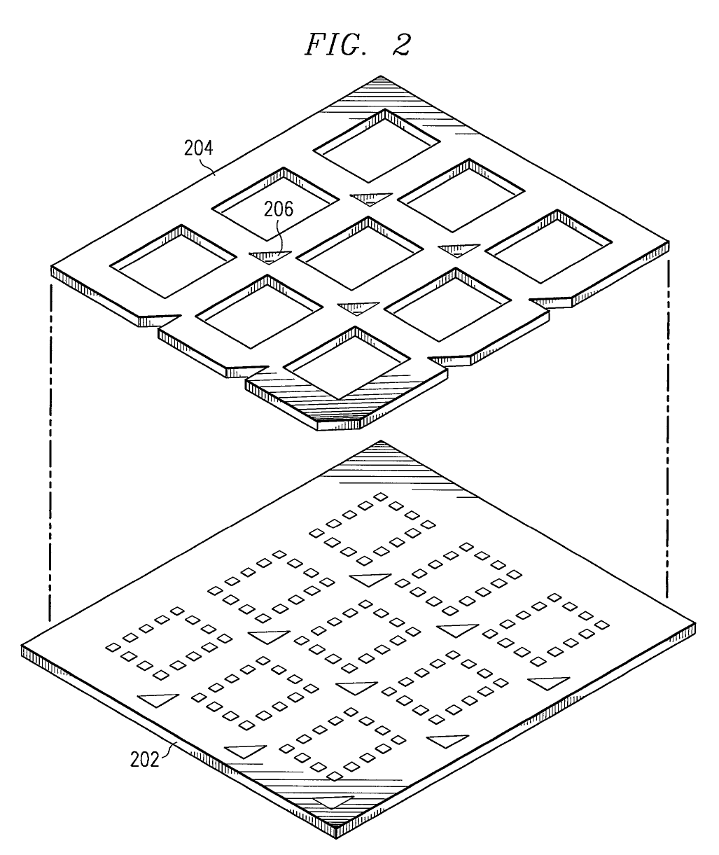

FIG. 2 is an exploded perspective view of sheets of material laminated to form the 15 package of FIG. 1. FIG. 2 illustrates how the void in the upper portion of the package is formed. A first sheet 202 of substrate material is formed. The first sheet includes the lower portion and the intermediate metalization layer for several package substrates, and any other necessary interconnection layers. A second sheet 204 of substrate material is formed to include voids 206 to form the package cavity and expose a region of the metalization layer. Like the first sheet, the second sheet will form the upper portion of several package substrates.

The first 202 and second 204 sheets typically are an unfired ceramic material. After the sheets have been assembled, they are fired. The fired sheet is then separated into individual substrates, typically by scribing and breaking the fired sheet. The edges of the individual substrates are then ground.

In addition to exposing a portion of the intermediate metalization layer, the void in the upper portion of the package may be used to physically position and align the packaged device. This is especially useful with electro-optical devices such as micromirror array. Micromirror arrays typically require precise alignment with eternal optical components. Typical integrated circuits do not require similar alignment since the position of the actual device is not important and may vary from package to package so long as the location of the package terminals remains constant.

One method of aligning the micromirror array to external optical components uses pre defined points on the package substrate and on the edge of the package substrate to define a reference plane. When the package is assembled, the micromirror array is placed at a predetermined point offset relative to the reference plane and the package edges. The system in which the packaged micromirror array is later installed holds the micromirror package by these 105 same regions so that the reference coordinates are consistently used. Early devices used the top surface of the package, or the top surface of the glass window to define a reference plane. The use of the top surface introduced variance in the location of the micromirror since the offset between the plane on which the micromirror was mounted and the top of the package was not well controlled.

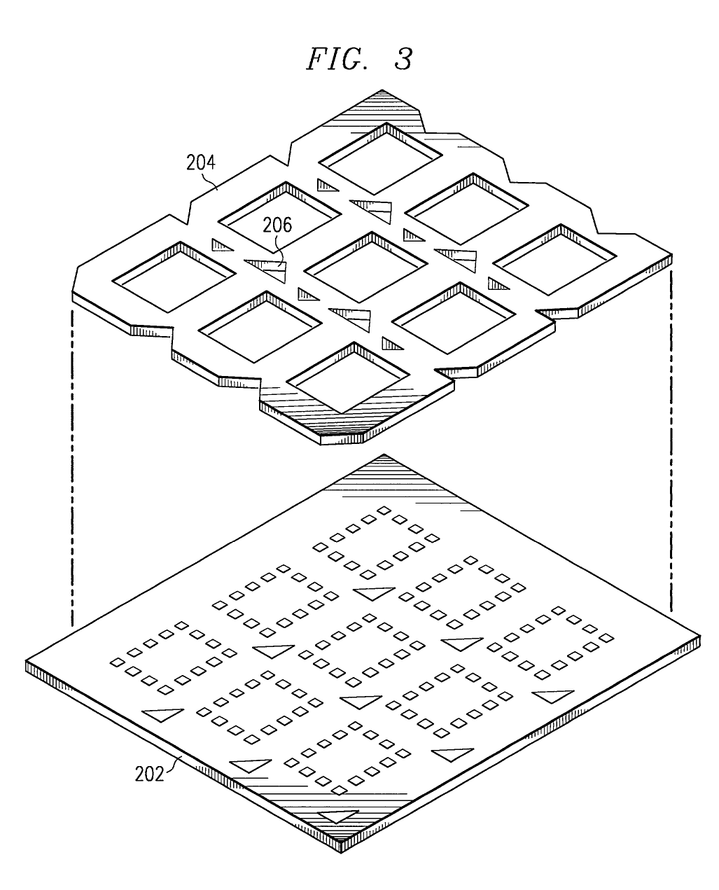

Modern packages provide voids in the upper portion of the package to allow access to the top surface of the lower portion of the package substrate. Since the micromirror is attached directly to this top surface, variances in the upper portion of the package do not affect the accuracy of the micromirror alignment. The void created to allow visual access to the intermediate metalization layer also provides mechanical access to this reference plane. FIG. 3 shows the sheets of substrate material from FIG. 2 with voids created to provide three points of mechanical access to the reference plane of each device.

Thus, although there has been disclosed to this point a particular embodiment for a low cost feature to indicate package orientation and method therefore, it is not intended that such specific references be considered limitations upon the scope of this invention except insofar as set forth in the following claims. Furthermore, having described the invention in connection with certain specific embodiments thereof, it is to be understood that further modifications may now suggest themselves to those skilled in the art. It is intended to cover all such modifications as fall within the scope of the appended claims. In the following claims, only elements denoted by the words “means for” are intended to be interpreted as means plus function claims under 35 U.S.C. § 112, paragraph six.

What is claimed is:

1. A substrate for a device package comprising:
a lower portion of a package;
an intermediate metalization layer on a top surface of said lower portion;
an upper portion of said package on said top surface of said lower portion, a corner portion of said intermediate metalization layer remaining visible beyond the extent of said upper portion for indicating an orientation of said substrate.

2. The substrate of claim 1, said lower and upper portions comprising a ceramic.

3. The substrate of claim 1, said lower portion comprising a layered ceramic portion containing electrical interconnections.

4. The substrate of claim 1, said visible corner portion comprising a plating on said visible corner portion.

5. The substrate of claim 1, comprising an electrical device electrically connected to portions of said metalization layer.

6. The substrate of claim 1, comprising an electrical device electrically connected to portions of said metalization layer, said visible corner portion electrically isolated from said portions of said metalization layer electrically connected to said device.

7. The substrate of claim 1, comprising an electrical device and a lid enclosing said device between said lid and said substrate.

8. The substrate of claim 1, said upper portion having a void over said visible corner region of said metalization layer, said void allowing visibility to said metalization layer.

9. The substrate of claim 8, said void used to mechanically position said substrate.

10. A method of forming a device package comprising:
providing a lower portion of a package;
providing an intermediate metalization layer on a top surface of said lower portion;
providing an upper portion of said package on said top surface of said lower portion, a corner portion of said intermediate metalization layer remaining visible beyond the extent of said upper portion for indicating an orientation of said substrate.

11. The method of claim 10, said providing a lower portion comprising providing a lower ceramic portion.

12. The method of claim 10, said providing an upper portion comprising providing an upper ceramic portion.

13. The method of claim 10, said providing a lower portion comprising providing a layered ceramic portion containing electrical interconnections.

14. The method of claim 10, comprising plating said visible corner portion.

15. The method of claim 10, comprising attaching a device to said substrate and electrically connecting portions of said metalization layer to said device.

16. The method of claim 11, comprising electrically isolating said visible corner portion from portions of said metalization layer electrically connected to said device.

17. The method of claim 10, comprising a lid enclosing said device between said lid and said substrate.

18. The method of claim 10, said providing an upper portion comprising providing an upper portion having a void over said visible corner region of said metalization layer, said void allowing visibility to said metalization layer.

19. The method of claim 18, comprising using said void to mechanically position said substrate.
